(19) United States
(12) Patent Application Publication
(10) Pub. No.: US 2011/0280037 A1
(43) Pub. Date: Nov. 17, 2011

(54) Optical pointing module having lighting function and electronic apparatus

(75) Inventors: Kwang Cheol Cho, Yongin (KR); Sang Jin Lee, Seoul (KR); Seung Hoon Han, Suwon (KR)

(73) Assignee: SAMSUNG ELECTRO-MECHANICS CO., LTD., Suwon (KR)

(21) Appl. No.: 13/067,006

(22) Filed: May 2, 2011

(30) Foreign Application Priority Data
May 11, 2010 (KR) 10-2010-0044194

(51) Int. Cl. H01S 3/034; H01L 33/02; G02B 27/20

(52) U.S. Cl. 362/553; 362/259; 362/555

(57) ABSTRACT

There are provided an optical pointing module having a lighting function and an electric device that can be used at night or dark place. An optical pointing module having a lighting function according to an aspect of the invention may include: a laser light source mounted on a printed circuit board; an outer housing through which laser light, emitted from the laser light source, passes, the outer housing having an outside part formed of a transparent material; and a lighting unit mounted inside the outer housing and supplying light to the outside part.

### CROSS-REFERENCE TO RELATED APPLICATIONS

This application claims the priority of Korean Patent Application No. 10-2010-0044194 filed on May 11, 2010, in the Korean Intellectual Property Office, the disclosure of which is incorporated herein by reference.

### BACKGROUND OF THE INVENTION

1. Field of the Invention

The present invention relates to an optical pointing module and an electric device, and more particularly, to an optical pointing module having a lighting function and an electric device that can be used at night or dark place.

2. Description of the Related Art

In general, personal mobile terminals, such as cellular phones or smartphones, have been employing user interfaces using keypads, which consist of a set of buttons in order to input numbers and letters as well as directional buttons.

Furthermore, in line with the commercialization of wireless Internet services such as wireless broadband (WIBRO) services, an operating system of a graphical user interface (GUI), which allows a user to perform an operation through the use of graphics, has been used in a personal mobile terminal when the user exchanges information with a computer.

That is, the GUI, which allows the user to perform an operation by selecting a menu on a screen, is used as a user interface of a personal mobile terminal by using a mouse or the like, there is an urgent need for an input device appropriate for the personal mobile terminal.

Correspondingly, touch keys, joysticks, and the like using an improved mono method of making a selection in a sequential manner, such as a keypad, on a display screen of a personal mobile terminal have appeared.

However, these touch keys and joysticks in the related art are difficult to use at night or dark place.

### SUMMARY OF THE INVENTION

An aspect of the present invention provides an optical pointing module having a lighting function and an electronic apparatus that can be used at night or dark place.

According to an aspect of the present invention, there is provided an optical pointing module having a lighting function, the optical pointing module including: a laser light source mounted on a printed circuit board; an outer housing through which laser light, emitted from the laser light source, passes, the outer housing having an outside part formed of a transparent material; and a lighting unit mounted inside the outer housing and supplying light to the outside part.

The outside part may be provided along a circumference of the outer housing and emits light from an upper surface of the outer housing.

The outside part may be provided along a circumference of the outer housing and emits light from side surfaces of the outer housing.

The lighting unit may include: at least one light emitting diode mounted on the printed circuit board and emitting light; and a light guide guiding the light, emitted from the at least one light emitting diode, in a predetermine direction.

The light guide may include an encapsulation part extended to the printed circuit board and surrounding the at least one light emitting diode.

A reflective surface may be provided on an outer surface of the light guide in order to guide light.

A leakage prevention surface may be provided on an outer surface of the encapsulation part in order to prevent leaks of the light emitted from the at least one light emitting diode.

The optical pointing module may further include: a light receiving unit located on the printed circuit board and receiving the laser light, reflected from the outer housing by an external stimulus to transmit an electrical signal to an integrated circuit; and an inner housing received in the outer housing and having a passage recess through which the laser light passes.

The inner housing may include a contact surface coming into contact with a lower surface of the light guide.

A surface of the inner housing, in which the passage recess may be provided, may be dented on the contact surface.

A bottom surface of the passage recess of the inner housing may include a light transmission hole through which the laser light, emitted from the laser light source, is transmitted, and a light-receiving hole through which the laser light, reflected from the outer housing, may be received.

The light receiving unit may include an image sensor receiving the laser light reflected from the outer housing.

The inner housing may be formed of polycarbonate.

The laser light source may be a vertical-cavity surface-emitting laser (VCSEL).

The optical pointing module may, further include a dome switch provided on a lower surface of the printed circuit board.

An area of the light-receiving hole may be greater than that of the light transmission hole.

The inner housing may include a first opening through which the encapsulation part of the light guide passes, and the light guide may include a second opening allowing the laser light to be emitted through the passage groove and the laser light being reflected to be input to the passage recess.

According to another aspect of the present invention, there is provided an electronic apparatus including: an optical pointing module having a laser light source mounted on a printed circuit board, an outer housing through which laser light, emitted from the laser light source, passes, the outer housing having an outside part formed of a transparent material, and a lighting unit mounted inside the outer housing and supplying light to the outside part; a casing receiving the optical pointing module therein and exposing the outer housing to an outside thereof; and a display displaying an image according to signal processing by the optical pointing module.

The electronic apparatus of claim 18, wherein the outside part may be provided along a circumference of the outer housing and emits light from an upper surface of the outer housing.

The outside part may be provided along a circumference of the outer housing and emits light from side surfaces of the outer housing.

The lighting unit may include: at least one light emitting diode mounted on the printed circuit board and emitting light; and a light guide guiding the light, emitted from the at least one light emitting diode, in a predetermined direction.

The light guide may include an encapsulation part extended to the printed circuit board and surrounding the at least one light emitting diode.

A reflective surface may be provided on an outer surface of the light guide in order to guide light.

A leakage prevention surface may be provided on an outer surface of the encapsulation part in order to prevent leaks of the light emitted from the at least one light emitting diode.

The optical pointing module may include: a light receiving unit located on the printed circuit board and receiving the light, reflected from the outer housing by an external stimulus to transmit an electrical signal to the integrated circuit; and an inner housing received in the outer housing and a passage recess through which the laser light passes.

The inner housing may include a contact surface coming into contact with a lower surface of the light guide.

A surface of the inner housing, through which the passage recess may be provided, may be dented on the contact surface.

A bottom surface of the passage recess of the inner housing may include a light transmission hole through which the laser light, emitted from the laser light source, is transmitted, and a light-receiving hole through which the laser light, reflected from the outer housing, may be received.

The light receiving unit may include an image sensor receiving the laser light reflected from the outer housing.

The inner housing may be formed of polycarbonate.

The laser light source may be a vertical-cavity surface-emitting laser (VCSEL).

The electronic apparatus may further a dome switch provided on a lower surface of the printed circuit board.

An area of the light-receiving hole may be greater than that of the light transmission hole.

The inner housing may include a first opening through which the encapsulation part of the light guide passes, and the light guide may include a second opening allowing the laser light to be emitted through the passage groove and the laser light being reflected to be input to the passage recess.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic perspective view illustrating an optical pointing module according to an exemplary embodiment of the present invention;

FIG. 2 is a schematic lower perspective view illustrating an optical pointing module according to an exemplary embodiment of the present invention;

FIG. 3 is a schematic exploded perspective view illustrating an optical pointing module according to an exemplary embodiment of the present invention;

FIG. 4 is a schematic sectional view illustrating an optical pointing module according to an exemplary embodiment of the present invention;

FIG. 5 is an upper view illustrating an inner housing of an optical pointing module according to an exemplary embodiment of the present invention;

FIG. 6 is a perspective view illustrating an optical pointing module according to an exemplary embodiment of the present invention; and

FIG. 7 is a schematic perspective view illustrating an electronic apparatus using an optical pointing module according to an exemplary embodiment of the present invention.

### DETAILED DESCRIPTION OF THE PREFERRED EMBODIMENT

Exemplary embodiments of the present invention will now be described in detail with reference to the accompanying drawings.

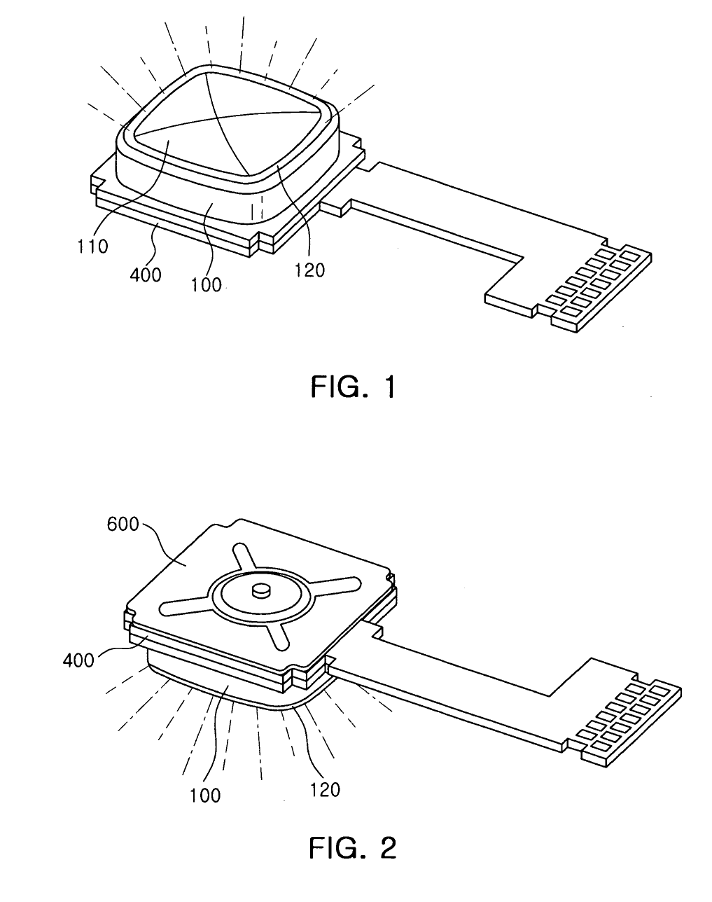

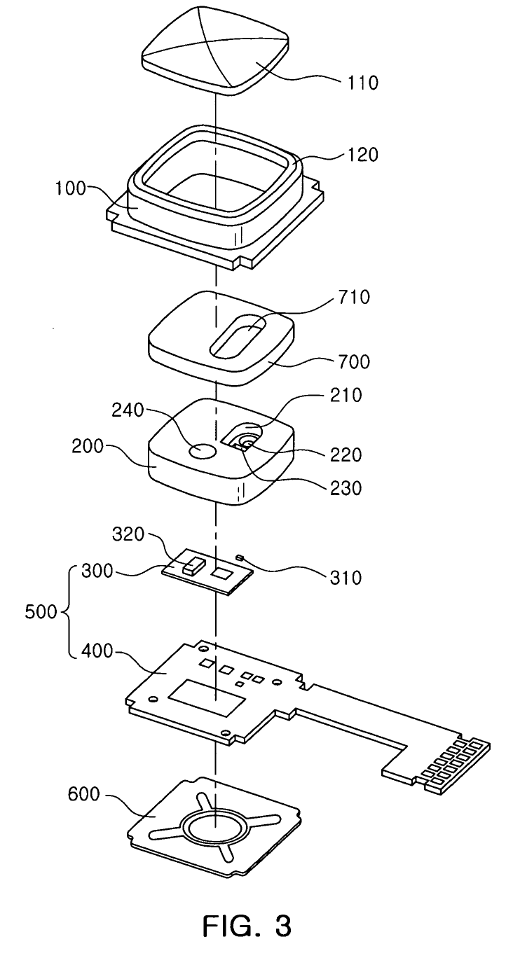

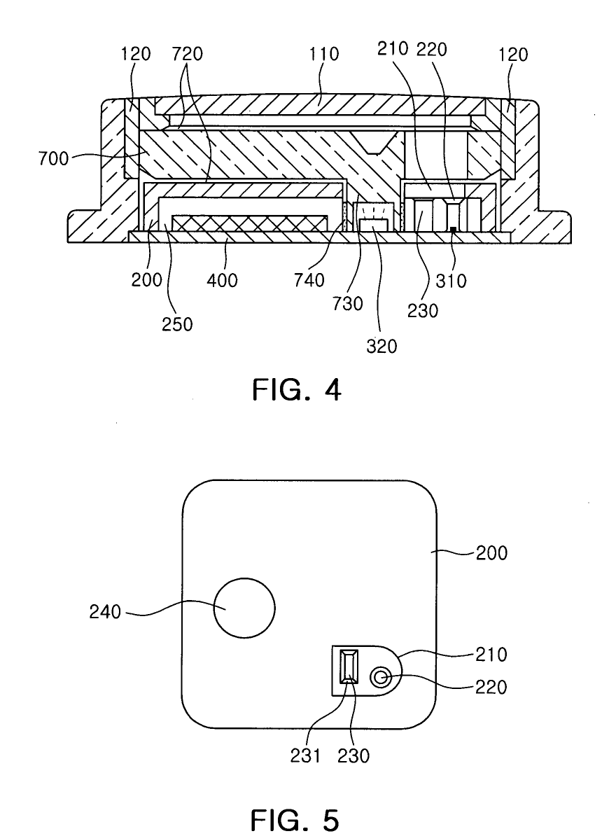

FIG. 1 is a schematic perspective view illustrating an optical pointing module according to an exemplary embodiment of the invention. FIG. 2 is a schematic lower perspective view schematically illustrating an optical pointing module according to an exemplary embodiment of the invention. FIG. 3 is a schematic exploded perspective view illustrating an optical pointing module according to an exemplary embodiment of the invention. FIG. 4 is a schematic sectional view illustrating an optical pointing module according to an exemplary embodiment of the invention.

Referring to FIGS. 1 through 4, an optical pointing module according to this embodiment may include an outer housing 100, an inner housing 200, a light receiving unit 500, and a dome switch 600.

Laser light, emitted from a laser light source 310 to be described below, is transmitted through the outer housing 100. An external stimulus is input to the outer housing 100.

The outer housing 100 accommodates the inner housing 200 and the light receiving unit 500, which form the optical pointing module according to this embodiment, and may be shaped like a cap with an opening in one surface thereof.

An upper surface of the outer housing 100 has a transmissive area through which light is transmitted. In terms of increasing durability and workability, the outer housing 100 may be manufactured by injection molding.

The outer housing 100 may be formed around the circumference of the outer housing 100 and include an outside part 120 emitting light, being supplied from lighting portions 700 and 320 to be described below, to the outside. The outside part 120 may emit light from both an upper surface of the outer housing 100 along the circumference of the outer housing 100 and side surfaces of the light outer housing 100.

Furthermore, the outer housing 100 is not limited to a square shape as this embodiment. The shape of the outer housing 100 can be modified by a person skilled in the art without departing from the spirit of the invention.

The lighting portions 700 and 320 may include a light guide 700 guiding light so that light can be supplied to the outside part 120 of the outer housing 100 and at least one light emitting diode (LED) 320 emitting light to the light guide 700.

Light, emitted from the at least one light emitting diode 320, is made incident upon the inside of the light guide 700. The light guide 70 comes into contact with a lower surface of the outer housing 100, thereby supplying the light to the outside part 120 of the outer housing 100. To this end, a reflective surface 720 may be formed on the outer surface of the light guide 700 so that the light, made incident inside the light guide 700, is reflected and guided in a predetermined direction. The reflective surface 720 may be formed by painting the outer surface of the light guide 700 silver.

The light guide 700 may include an encapsulation part 730 that is extended to the printed circuit board 400 and surrounds the light emitting diode 320. A leakage prevention surface 740 may be formed on the outer surface of the encapsulation part 730 in order to prevent leaks of light, emitted from the light emitting diode 320. The leakage prevention surface 740 may be formed by painting the outer surface of the encapsulation part 730 black.

In addition, the light guide 700 may have a second opening 710 through which the laser light passes.

The inner housing 200 is received inside the outer housing 100 and may have a passage recess 210 in an upper surface thereof coming into contact with the outer housing 100. The laser light passes through the passage recess 210. Here, the upper surface of the inner housing 200 is dented to form the passage recess 210. However, the invention is not limited thereto.

An inner surface 215 of the passage recess 210 serves to shield external light when laser light, emitted from a laser light source 310 to be described below, is reflected from the light guide 700 and is received in an image sensor (not shown) of an integrated circuit 300.

Furthermore, in the same manner as the inner surface 215 of the passage recess 210, an outer surface of the inner housing 200 that comes into contact with the inner surface of the light guide 700 serves to shield external light.

The laser light, reflected from the outer housing 100, is received in the image sensor (not shown) of the light receiving unit 500 and computes a position on a display (not shown) of an electronic apparatus by the integrated circuit 300.

Here, the inflow of external light hinders the operation of computing a position through the integrated circuit 300, and thus it becomes impossible to indicate an accurate position thereof on the display (not shown).

Therefore, the external light is shielded by the outer surface of the inner housing 200, which comes into contact with the inner surface of the outer housing 100, and the inner surface 215 of the passage recess 210. A description of the passage recess 210 will be made below with reference to FIG. 4.

The passage recess 210 of the inner housing 200 may have a light transmission hole 220 and a light-receiving hole 230.

The light transmission hole 220 is formed in a bottom surface of the passage recess 210 and serves as a path through which laser light, emitted from the laser light source 310, is made incident upon the outer housing 100. The laser light, passing through the light transmission hole 220, is transmitted through a predetermined region of the outer housing 100.

The light transmission hole 220 may have a circular shape but the present invention is not limited thereto.

The light-receiving hole 230 is also formed in the bottom surface of the passage recess 212 and serves as a path through which laser light, being transmitted through the outer housing 100, is reflected by an external stimulus and received in the image sensor (not shown). The light-receiving hole 230 may have a square shape, but the present invention is not limited thereto. Here, the laser light being emitted and the laser light being reflected may be transmitted through the second opening 710 of the light guide 700.

Furthermore, a first opening 240 may be formed in the inner housing 200 so that the light, emitted from the light emitting diode 320, can be transmitted to the light guide 700. The encapsulation part 730 of the light guide 700 is injected through the first opening 240 to thereby surround the light emitting diode 320.

A receiving recess 250 is a space in which the light receiving unit 500 is received, and will be described below with reference to FIG. 4.

The light receiving unit 500 may include the integrated circuit 300 and a printed circuit board 400. The integrated circuit 300 may include the image sensor (not shown).

The image sensor (not shown) of the integrated circuit 300 receives the laser light, passing through the light-receiving hole 230 of the inner housing 200, and computes a position value on a display (not shown) to thereby indicate an accurate position on the display (not shown).

The circuit board 400 transmits an electrical signal of the integrated circuit 300 to the display (not shown) in order to indicate an accurate position on the display (not shown).

The laser light source 310, which becomes a source of laser light, and the light emitting diode 320 may be located on the printed circuit board 400.

The laser light source 310 may be a vertical-cavity surface-emitting laser (VCSEL). Hereinafter, the laser light source 310 may also be referred to as a vertical-cavity surface-emitting laser 310.

The vertical-cavity surface-emitting laser 310 is a type of laser diode that converts an electrical signal into an optical signal.

The vertical-cavity surface-emitting laser 310 is a new light source that will replace an existing lateral light emitting semiconductor (FP or DFB). The vertical-cavity surface-emitting laser 310 replaces a photoelectric sensor such as an infrared light emitting diode (LED) sensor module, thereby manufacturing a precision photoelectric sensor.

The dome switch 600 may be located under the circuit board 400 in order to indicate an accurate position on the display (not shown) by the external stimulus.

Referring to FIG. 4, the inner housing 200, as described above, may include the receiving recess 250 in addition to the passage recess 210, the light transmission hole 220, and the light-receiving hole 230.

In an optical pointing module, the receiving recess 250 is a space in which accessory devices are located. The size and kind of the accessory devices may be varied according to an electronic apparatus including the above-described optical pointing module.

Furthermore, the inner housing 200 may be received in the outer housing 100 and come into contact with the inner surface of the light guide 700 except for the passage recess 210, the light transmission hole 220, the light-receiving hole 230, and the receiving recess 250.

As described above, external light is thereby shielded by the outer surface of the inner housing 200 that comes into contact with the inner surface of the light guide 700.

Here, the inner housing 200 may be formed of polycarbonate. Polycarbonate, which is resins made by polymerizing carbonates, is as strong as a metal while being acid and heat-resistant.

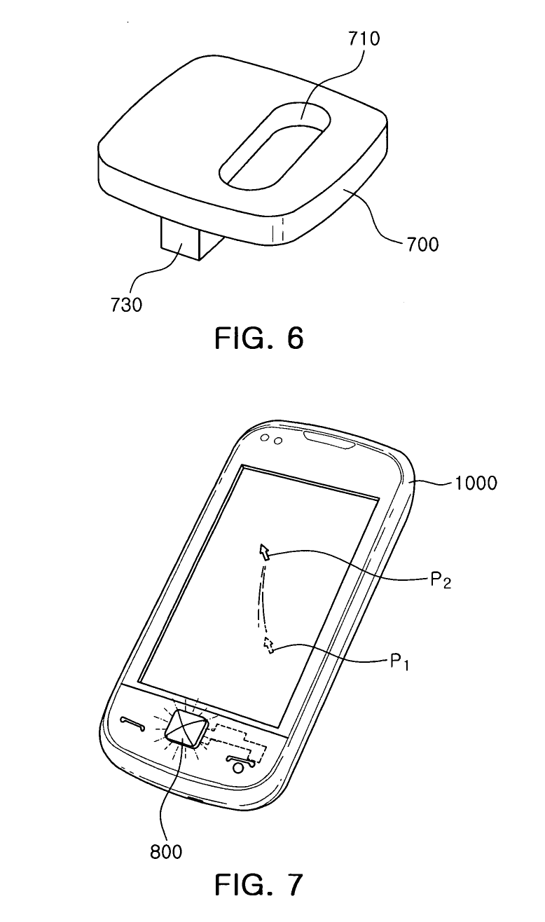

FIG. 5 is a view illustrating an upper view illustrating an inner housing of an optical pointing module according to an exemplary embodiment of the invention. FIG. 6 is a perspective view illustrating a light guide of an optical pointing module according to an exemplary embodiment of the invention. FIG. 7 is a schematic perspective view illustrating an electronic apparatus using an optical pointing module according to an exemplary embodiment of the invention.

As shown in FIG. 5, the inner housing 200 of the optical pointing module according to this embodiment has the passage recess 210, which is recessed to be lower than the outer surface thereof that comes into contact with the inner surface of the outer housing 100. The passage recess 210 may have the light transmission hole 220 through which laser light is transmitted and the light-receiving hole 230 in which laser light, reflected by an external stimulus such as a finger located on the surface of the outer housing 100. Furthermore, the inner housing 200 may also have the first opening 240 through which the encapsulation part 730 of the light guide 700 can pass.

In terms of the directionality of laser light and receiving reflected laser light, the area of the light-receiving hole may be larger than that of the light transmission hole.

As shown in FIG. 6, the light guide 700 according to this embodiment may have the second opening 710 and the encapsulation part 730. Here, laser light, emitted through the light transmission hole 220 of the inner housing 200, and reflected laser light, made incident upon the light-receiving hole 230, pass through the second opening 710. The encapsulation part 730 may surround the light emitting diode 320 through the first opening 240 of the inner housing 200.

Referring to FIG. 7, an electronic apparatus using an optical pointing module according to an exemplary embodiment of the invention, in particular, a mobile communications terminal 1000 can display an image, appearing on a display of the mobile communications terminal 1000, by providing a stimulus on an outer housing of an optical pointing module 800 by using a finger. In particular, a clear view is secured by light emitted from the optical pointing module 800 at night or dark place, thereby readily moving positions (p1 and p2) of a cursor on the mobile communications terminal 1000.

As set forth above, according to exemplary embodiments of the invention, as an optical pointing module and an electronic apparatus have a lighting function, they can be used at night or dark place.

While the present invention has been shown and described in connection with the exemplary embodiments, it will be apparent to those skilled in the art that modifications and variations can be made without departing from the spirit and scope of the invention as defined by the appended claims.

What is claimed is:

1. An optical pointing module having a lighting function, the optical pointing module comprising:
a laser light source mounted on a printed circuit board;
an outer housing through which laser light, emitted from the laser light source, passes, the outer housing having an outside part formed of a transparent material; and
a lighting unit mounted inside the outer housing and supplying light to the outside part.

2. The optical pointing module of claim 1, wherein the outside part is provided along a circumference of the outer housing and emits light from an upper surface of the outer housing.

3. The optical pointing module of claim 1, wherein the outside part is provided along a circumference of the outer housing and emits light from side surfaces of the outer housing.

4. The optical pointing module of claim 1, wherein the lighting unit comprises:
at least one light emitting diode mounted on the printed circuit board and emitting light; and
a light guide guiding the light, emitted from the at least one light emitting diode, in a predetermine direction.

5. The optical pointing module of claim 4, wherein the light guide comprises an encapsulation part extended to the printed circuit board and surrounding the at least one light emitting diode.

6. The optical pointing module of claim 5, wherein a reflective surface is provided on an outer surface of the light guide in order to guide light.

7. The optical pointing module of claim 5, wherein a leakage prevention surface is provided on an outer surface of the encapsulation part in order to prevent leaks of the light emitted from the at least one light emitting diode.

8. The optical pointing module of claim 5, further comprising:
a light receiving unit located on the printed circuit board and receiving the laser light, reflected from the outer housing by an external stimulus to transmit an electrical signal to an integrated circuit; and
an inner housing received in the outer housing and having a passage recess through which the laser light passes.

9. The optical pointing module of claim 8, wherein the inner housing comprises a contact surface coming into contact with a lower surface of the light guide.

10. The optical pointing module of claim 8, wherein a surface of the inner housing, in which the passage recess is provided, is dented on the contact surface.

11. The optical pointing module of claim 10, wherein a bottom surface of the passage recess of the inner housing comprises a light transmission hole through which the laser light, emitted from the laser light source, is transmitted, and a light-receiving hole through which the laser light, reflected from the outer housing, is received.

12. The optical pointing module of claim 8, wherein the light receiving unit comprises an image sensor receiving the laser light reflected from the outer housing.

13. The optical pointing module of claim 8, wherein the inner housing is formed of polycarbonate.

14. The optical pointing module of claim 1, wherein the laser light source is a vertical-cavity surface-emitting laser (VCSEL).

15. The optical pointing module of claim 1, further comprising a dome switch provided on a lower surface of the printed circuit board.

16. The optical pointing module of claim 11, wherein an area of the light-receiving hole is greater than that of the light transmission hole.

17. The optical pointing module of claim 8, wherein the inner housing comprises a first opening through which the encapsulation part of the light guide passes, and
the light guide comprises a second opening allowing the laser light to be emitted through the passage groove and the laser light being reflected to be input to the passage recess.

18. An electronic apparatus comprising:
an optical pointing module having a laser light source mounted on a printed circuit board, an outer housing through which laser light, emitted from the laser light source, passes, the outer housing having an outside part formed of a transparent material, and a lighting unit mounted inside the outer housing and supplying light to the outside part;
a casing receiving the optical pointing module therein and exposing the outer housing to an outside thereof; and
a display displaying an image according to signal processing by the optical pointing module.

19. The electronic apparatus of claim 18, wherein the outside part is provided along a circumference of the outer housing and emits light from an upper surface of the outer housing.

20. The electronic apparatus of claim 18, wherein the outside part is provided along a circumference of the outer housing and emits light from side surfaces of the outer housing.

21. The electronic apparatus of claim 18, wherein the lighting unit comprises:
at least one light emitting diode mounted on the printed circuit board and emitting light; and
a light guide guiding the light, emitted from the at least one light emitting diode, in a predetermined direction.

22. The electronic apparatus of claim 21, wherein the light guide comprises an encapsulation part extended to the printed circuit board and surrounding the at least one light emitting diode.

23. The electronic apparatus of claim 22, wherein a reflective surface is provided on an outer surface of the light guide in order to guide light.

24. The electronic apparatus of claim 22, wherein a leakage prevention surface is provided on an outer surface of the encapsulation part in order to prevent leaks of the light emitted from the at least one light emitting diode.

25. The electronic apparatus of claim 22, wherein the optical pointing module comprises:
a light receiving unit located on the printed circuit board and receiving the light, reflected from the outer housing by an external stimulus to transmit an electrical signal to the integrated circuit; and
an inner housing received in the outer housing and a passage recess through which the laser light passes.

26. The electronic apparatus of claim 25, wherein the inner housing comprises a contact surface coming into contact with a lower surface of the light guide.

27. The electronic apparatus of claim 26, wherein a surface of the inner housing, through which the passage recess is provided, is dented on the contact surface.

28. The electronic apparatus of claim 27, wherein the a bottom surface of the passage recess of the inner housing includes a light transmission hole through which the laser light, emitted from the laser light source, is transmitted, and a light-receiving hole through which the laser light, reflected from the outer housing, is received.

29. The electronic apparatus of claim 25, wherein the light receiving unit comprises an image sensor receiving the laser light reflected from the outer housing.

30. The electronic apparatus of claim 25, wherein the inner housing is formed of polycarbonate.

31. The electronic apparatus of claim 18, wherein the laser light source is a vertical-cavity surface-emitting laser (VCSEL).

32. The electronic apparatus of claim 18, further comprising a dome switch provided on a lower surface of the printed circuit board.

33. The electronic apparatus of claim 28, wherein an area of the light-receiving hole is greater than that of the light transmission hole.

34. The electronic apparatus of claim 25, wherein the inner housing comprises a first opening through which the encapsulation part of the light guide passes, and
the light guide comprises a second opening allowing the laser light to be emitted through the passage groove and the laser light being reflected to be input to the passage recess.
